(19) United States
(12) Patent Application Publication
(10) Pub. No.: US 2015/0263228 A1
(43) Pub. Date: Sep. 17, 2015

(54) NITRIDE SEMICONDUCTOR LIGHT-EMITTING DEVICE HAVING EXCELLENT BRIGHTNESS AND ESD PROTECTION PROPERTIES

(71) Applicant: ILJIN LED CO., LTD, Ansan-si Gyeonggi-do (KR)

(72) Inventors: Won-Yong Lee, Gyeonggi-do (KR); Jung-Won Park, Yongin-si Gyeonggi-do (KR); Sung-Hak Lee, Incheon (KR); Tae-Wan Kwon, Seoul (KR); Won-Jin Choi, Seongnam-si Gyeonggi-do (KR)

(21) Appl. No.: 14/436,692

(22) PCT Filed: Oct. 15, 2013
(86) PCT No.: PCT/KR2013/009209

§ 371 Date: Apr. 17, 2015

(30) Foreign Application Priority Data
Oct. 22, 2012 (KR) 10-2012-0117239

(51) Int. Cl. H01L 33/14; H01L 33/32

(52) U.S. Cl. CPC H01L 33/145; H01L 33/325

(57) ABSTRACT

Disclosed is a nitride semiconductor light-emitting device having excellent brightness and ESD protection properties. The nitride semiconductor light-emitting device according to the present invention includes an electron blocking layer that is disposed between a p-type nitride semiconductor layer and an active layer, wherein said electron blocking layer includes AlInGaN, and the concentration of indium increases in the electron blocking layer as said layer progressively moves away from the active layer.

### TECHNICAL FIELD

The present invention relates to a nitride semiconductor light-emitting device, and more particularly, to a nitride semiconductor light-emitting device that can exhibit excellent brightness and electrostatic discharge (ESD) characteristics as a result of controlling the composition of an electron blocking layer (EBL) formed between an active layer and a p-type nitride semiconductor layer.

### BACKGROUND ART

A light-emitting device is a device that emits light upon the recombination of electrons and holes.

Typical light-emitting devices include a nitride semiconductor light-emitting device based on a nitride semiconductor represented by GaN. The nitride semiconductor light-emitting device has a high band gap, and thus can emit various colored lights. In addition, it has excellent thermal stability, and thus has been used in various fields.

FIG. 1 shows a general nitride semiconductor light-emitting device.

Referring to FIG. 1, the nitride semiconductor light-emitting device generally has a structure in which an n-type nitride semiconductor layer 110, an active layer 120 and a p-type nitride semiconductor layer 130 are sequentially formed on a substrate. For hole injection, a p-electrode pad that is electrically connected to the p-type nitride semiconductor layer 130 may be formed, and for electron injection, an n-electrode pad that is electrically connected to the n-type nitride semiconductor layer may be formed.

Meanwhile, between the active layer 120 and the p-type nitride semiconductor layer 130, an electron blocking layer (EBL) may further be formed. The electron blocking layer functions to prevent electrons, supplied from the n-type nitride semiconductor layer 110, from overflowing to the p-type semiconductor layer 130.

The electron blocking layer is generally formed of AlGaN. The electron blocking layer formed of AlGaN has a high ability to block electrons, but has a problem in that it also acts as a hole barrier.

Prior art documents related to the present invention include Korean Patent Laid-Open Publication No. 10-2010-0070250 (published on Jun. 25, 2010). The patent document discloses a nitride semiconductor light-emitting device comprising an electron blocking layer including an AlGaN layer.

### DISCLOSURE

### Technical Problem

It is an object of the present invention to provide a nitride semiconductor light-emitting device that can exhibit excellent brightness and electrostatic discharge (ESD) protection characteristics by increasing the amount of holes supplied to an active layer, as a result of controlling the composition of an electron blocking layer which is formed between a p-type nitride semiconductor layer and the active layer in order to prevent electrons from overflowing to the p-type nitride semiconductor layer.

### Technical Solution

In an embodiment of the present invention, a nitride semiconductor light-emitting device includes: a first conductivity-type nitride semiconductor layer; an active layer formed on the first conductivity-type nitride semiconductor layer; a second conductivity-type nitride semiconductor layer formed on the active layer; and an electron blocking layer formed between one of the first conductivity-type nitride semiconductor layer and the second conductivity-type nitride semiconductor layer, which is formed of a p-type nitride semiconductor, and the active layer, in which the electron blocking layer contains indium (In), and the concentration of indium (In) in the electron blocking layer increases as the electron blocking layer moves away from the active layer.

The electron blocking layer may include AlInGaN doped with a p-type impurity. In this case, the concentration of the p-type impurity in the electron blocking layer may increase as the electron blocking layer moves away from the active layer.

In another embodiment of the present invention, a nitride semiconductor light-emitting device includes: a first conductivity-type nitride semiconductor layer; an active layer formed on the first conductivity-type nitride semiconductor layer; a second conductivity-type nitride semiconductor layer formed on the active layer; and an electron blocking layer formed between one of the first conductivity-type nitride semiconductor layer and the second conductivity-type nitride semiconductor layer, which is formed of a p-type nitride semiconductor, and the active layer, in which the electron blocking layer includes a hole diffusion layer, a hole transport layer and a hole injection layer in a direction moving away from the active layer, and each of the hole diffusion layer, the hole transport layer and the hole injection layer contains indium (In) such that the average indium concentration of the hole injection layer is higher than the average indium concentration of the hole injection layer and the average indium concentration of the hole transport layer.

Each of the hole diffusion layer, the hole transport layer and the hole injection layer may include AlInGaN doped with a p-type impurity. In this case, the average doping concentration of the p-type impurity in the hole injection layer may be higher than the average doping concentration of the p-type impurity in the hole diffusion layer and the average doping concentration of the p-type impurity in the hole transport layer.

### Advantageous Effects

The nitride semiconductor light-emitting device according to the present invention includes the electron blocking layer which includes p-type impurity-doped AlInGaN such that the concentration of indium (In) increases as the electron blocking layer moves away from the active layer. Thus, the amount of p-type impurities such as magnesium (Mg), which is added to the electron blocking layer, can be increased so that holes supplied from the p-type nitride semiconductor layer can smoothly move to the active layer. As a result, the nitride semiconductor light-emitting device according to the present invention can exhibit high brightness characteristics, because the probability of recombination of electrons and holes can be increased.

In addition, the nitride semiconductor light-emitting device according to the present invention has an advantage in that it has an excellent electrostatic discharge (ESD) protection effect, because the electron blocking layer offers a high current dispersion effect due to the addition of indium.

### BRIEF DESCRIPTION OF DRAWINGS

FIG. 1 shows a general nitride semiconductor light-emitting device.

FIG. 2 schematically shows a nitride semiconductor light-emitting device according to an embodiment of the present invention.

FIG. 3 shows an example of an electron blocking layer that can be applied to the present invention.

FIG. 4 shows the concentration profile of each of components contained in an electron blocking layer used in Example 1 of the present invention.

FIG. 5 shows the concentration profile of each of components contained in an electron blocking layer used in Comparative Example 1.

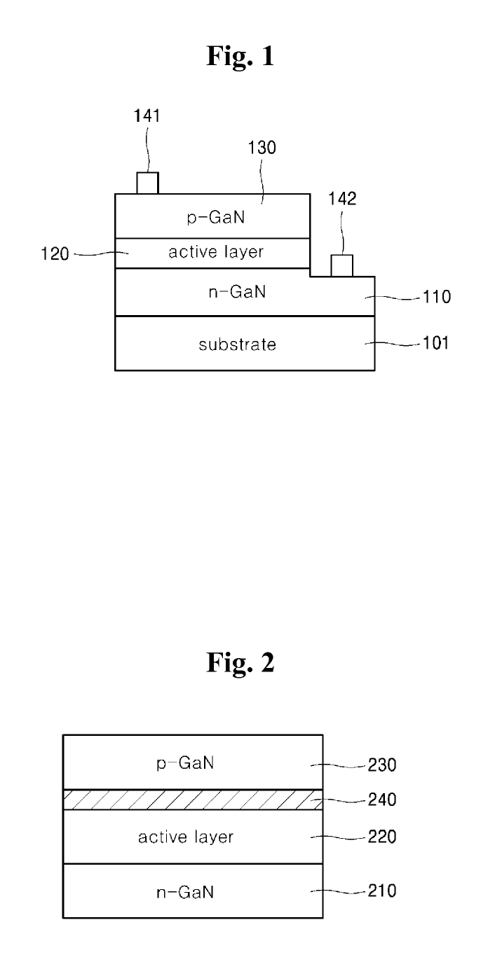

### MODE FOR INVENTION

Hereinafter, a nitride semiconductor light-emitting device having high brightness according to the present invention will be described in detail with reference to the accompanying drawings.

FIG. 2 schematically shows a nitride semiconductor light-emitting device according to an embodiment of the present invention.

Referring to FIG. 2, the nitride semiconductor light-emitting device according to the present invention includes a first conductivity-type nitride semiconductor layer 210, an active layer 220, a second conductivity-type nitride semiconductor layer 230 and an electron blocking layer 240.

As not shown in the figure, the nitride semiconductor light-emitting device according to the present invention may, if necessary, further include elements, including a buffer layer formed of AlN, an undoped nitride layer, a p-electrode pad and an n-electrode pad, which are required for improvement in crystal quality, electron injection and hole injection.

Meanwhile, in the nitride semiconductor light-emitting device shown in FIG. 2, the first conductivity-type nitride semiconductor layer 210 is an n-type nitride semiconductor layer doped with an n-type impurity such as silicon (Si), and the second conductivity-type nitride semiconductor layer 230 is a p-type nitride semiconductor layer doped with a p-type impurity such as magnesium. Also, the electron blocking layer 240 is formed between the active layer 220 and the second conductivity-type nitride semiconductor layer 230.

However, the nitride semiconductor light-emitting device according to the present invention is not necessarily limited to the example shown in FIG. 2. Specifically, the first conductivity-type nitride semiconductor layer 210 may be a p-type nitride semiconductor layer, and the second conductivity-type nitride semiconductor layer 230 may be an n-type nitride semiconductor layer, and the electron blocking layer 240 may be formed between the active layer 220 and the first conductivity-type nitride semiconductor layer 210.

In the nitride semiconductor light-emitting device according to the present invention, the electron blocking layer 240 is formed between one of the first conductivity-type nitride semiconductor layer 210 and the second conductivity-type nitride semiconductor layer 230, which is formed of a p-type nitride semiconductor (the layer 230 in FIG. 2). The electron blocking layer 240 is formed of a material such as AlGaN, which has band gap energy higher than that of GaN, so as to act as an electron barrier. Thus, it functions to prevent electrons, supplied from the layer (210 in FIG. 2) formed of an n-type nitride semiconductor, from overflowing to the layer (230 in FIG. 2) formed of a p-type nitride semiconductor.

As described above, a conventional electron blocking layer is formed of AlGaN. This electron blocking layer has an excellent ability to block electrons, but acts as a factor that reduces the probability of recombination of electrons and holes by interfering with the transport of holes.

However, the electron blocking layer 240 in the nitride semiconductor light-emitting device according to the present invention is characterized in that it includes AlInGaN doped with a p-type impurity, and the concentration of indium (In) in the electron blocking layer 240 increases as the electron blocking layer 240 moves away from the active layer 220. Herein, “the concentration of indium increases as the electron blocking layer moves away from the active layer” means that the concentration of indium increases throughout the electron blocking layer as the electron blocking layer moves away from the active layer, and does not mean that the concentration of indium increases continuously in the thickness direction of the electron blocking layer.

The p-type impurity that is contained in the electron blocking layer may include at least one of magnesium (Mg), beryllium (Be), zinc (Zn) and cadmium (Cd).

When the electron blocking layer whose indium (In) concentration was controlled as described above was used, it could be seen that the brightness was about 3% higher than that of a nitride semiconductor light-emitting device including an AlGaN-based electron blocking layer, under the same conditions.

In addition, the electron blocking layer whose indium (In) concentration was controlled as described above was used, it exhibited an excellent electrostatic discharge (ESD) protection effect, suggesting that the electron blocking layer that is applied in the present invention has an excellent current dispersion effect due to the addition of indium.

The concentration of aluminum (Al) in the electron blocking layer 240 preferably increases as the wavelength of light emitted from the active layer decreases.

In the case of a nitride semiconductor light-emitting device that emits light having a blue wavelength from the active layer, the concentration of aluminum (Al) in the electron blocking layer is preferably 15-20% of the total atomic number of aluminum (Al), indium (In) and gallium (Ga). If the concentration of aluminum in the electron blocking layer of the nitride semiconductor layer that mainly emits blue light from the active layer is lower than 15%, the electron blocking efficiency can be reduced. On the other hand, if the concentration of aluminum is higher than 20%, the hole transport efficiency can be reduced.

Meanwhile, in the case of a nitride semiconductor light-emitting device that emits light having a UV wavelength from the active layer, the concentration of aluminum (Al) in the electron blocking layer is preferably 20% or higher, and more preferably 20-25% of the sum of the total atomic number of aluminum (Al), indium (In) and gallium (Ga). This is because, in the case of the nitride semiconductor light-emitting device that mainly emits UV light from the active layer, the amount of indium (In) incorporated in the quantum well of the active layer is small, and thus the quantum well depth of the active layer is shallow so that there is a high possibility that electrons overflow from the quantum well of the active layer to the electron blocking layer.

In addition, in the case of a nitride semiconductor light-emitting device that emits light having a green wavelength from the active layer, the concentration of aluminum (Al) in the electron blocking layer is preferably lower than 15%, and more preferably 10-15% of the total atomic number of aluminum (Al), indium (In) and gallium (Ga). This is because, in the case of the nitride semiconductor light-emitting device that mainly emits green light from the active layer, the amount of indium (In) incorporated in the quantum well of the active layer is large, and thus the quantum well depth of the active layer is relatively deep so that the number of electrons remaining in the quantum well of the active layer will increase, suggesting that the possibility that electrons overflow to the electron blocking layer is relatively low.

In addition, the concentration of indium (In) in the electron blocking layer 240 is preferably 0.2-1.5% of the total atomic number of aluminum (Al), indium (In) and gallium (Ga). If the concentration of indium in the electron blocking layer is lower than 0.2%, the effect of increasing the efficiency with which holes are transported into the active layer will be insufficient. On the other hand, it is very difficult that the concentration of indium in the electron blocking layer is higher than 1.5%.

Meanwhile, when the concentration of indium in the electron blocking layer 240 was controlled as described above, it could be seen that, as the electron blocking layer moved away from the active layer 220, the concentration of the p-type impurity in the electron blocking layer increased in proportion to the concentration of indium, and in this case, the mobility of holes supplied from the layer (230 in FIG. 2) formed of a p-type nitride semiconductor can further be increased. The doping concentration of a p-type impurity such as Mg can increase in proportion to an increase in the indium (In) concentration of a portion adjacent to the p-type nitride semiconductor layer in the quaternary electron blocking layer, and thus the activation of holes will increase. Thus, the number of holes that can be injected into the active layer will increase, thus contributing to an increase in the brightness.

In the case in which the indium concentration is controlled in the thickness direction, the concentration of a p-type impurity in the electron blocking layer 240, which includes a p-type impurity that is diffused to the uppermost portion of the active layer, is preferably 1×10¹⁸ to 5×10²⁰ atoms/cm³. If the concentration of the p-type impurity is lower than 1×10¹⁸ atoms/cm³, the mobility of holes can be reduced. On the other hand, the concentration of the p-type impurity is higher than 5×10²⁰ atoms/cm³, the overall characteristics of the light-emitting device can be deteriorated due to the excessively high concentration of the p-type impurity.

In addition, the electron blocking layer 240 is preferably formed to a thickness of 5-100 nm. If the thickness of the electron blocking layer is less than 5 nm, the electron blocking layer cannot sufficiently perform its function. On the other hand, if the thickness of the electron blocking layer is more than 100 nm, the resistance component to the active layer direction in the p-type nitride material will increase to make hole injection difficult, thus deteriorating the brightness or forward voltage drop (Vf) characteristics.

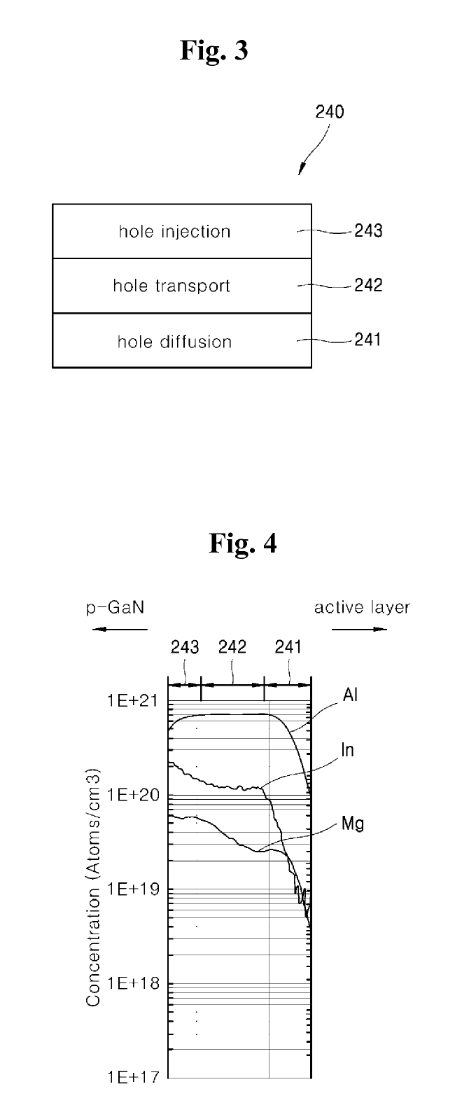

FIG. 3 shows an example of an electron blocking layer that can be applied to the present invention.

Referring to FIG. 3, the electron blocking layer 240 may include a hole diffusion layer 241, hole transport layer 242 and a hole injection layer 243 in a direction moving away from the active layer.

The hole injection layer 243 functions to inject holes from the layer (230 in FIG. 2) made of a p-type nitride semiconductor into the electron blocking layer 240. The hole transport layer 242 allows holes in the electron blocking layer 240 to be transported to the hole diffusion layer 241. The hole diffusion layer 241 functions to diffuse the transported holes to the active layer 220.

Herein, each of the hole diffusion layer 241, the hole transport layer 242 and the hole injection layer 243 includes AlInGaN doped with a p-type impurity. Particularly, the electron blocking layer is characterized in that the average indium concentration of the hole injection layer 243 is higher than the average indium concentration of the hole diffusion layer 241 and the average indium concentration of the hole transport layer 242. In addition, the average indium concentration of the hole transport layer 242 may be higher than the average indium concentration of the hole diffusion layer 241. As the average indium concentration of the hole injection layer 243 is the highest, the amount of a p-type impurity such as magnesium (Mg), which is added to the electron blocking layer 240, can be increased, and thus holes can be smoothly diffused from the layer (230 in FIG. 2) made of a p-type nitride semiconductor to the inside of the electron blocking layer 240 and to the active layer 220.

As a result of controlling the indium concentration as described above, the transport of holes from the layer (230 in FIG. 2) made of a p-type nitride semiconductor to the active layer 220 can be facilitated.

Meanwhile, the concentration of indium can show a tendency to increase progressively from the hole diffusion layer 241 to the hole transport layer 242 and from the hole transport layer 242 to the hole injection layer 243. Herein, “the concentration of indium shows a tendency to increase continuously” means that the indium concentration generally has a tendency to increase throughput the electron blocking layer, and does not mean that the indium concentration should increase continuously.

In addition, as a result of controlling the concentration of indium as described above, the average doping concentration of the p-type impurity in the hole injection layer 243 may be higher than the average doping concentration of the p-type impurity in the hole diffusion layer 241 and the average doping concentration of the p-type impurity in the hole transport layer 242. Further, the average doping concentration of the p-type impurity in the hole transport layer 242 may be higher than the average doping concentration of the p-type impurity in the hole diffusion layer 241. In addition, like the concentration of indium, the concentration of the p-type impurity can show a tendency to increase from the hole diffusion layer 241 to the hole transport layer 242 and from the hole transport layer 242 to the hole injection layer 243.

### EXAMPLES

Hereinafter, the construction and effect of the present invention will be descried in further detail with reference to preferred examples. It is to be understood, however, that these examples are for illustrative purposes only and are not intended to limit the scope of the present invention in any way. Contents not disclosed herein can be sufficiently understood by those skilled in the art, and thus the description thereof is omitted.

FIG. 4 shows the concentration profile of each of components contained in an electron blocking layer used in Example 1 of the present invention. As shown in FIG. 4, the electron blocking layer used in Example 1 was formed of AlInGaN, and the concentration of magnesium in the electron blocking layer showed a tendency to increase as the electron blocking layer moved away from the active layer.

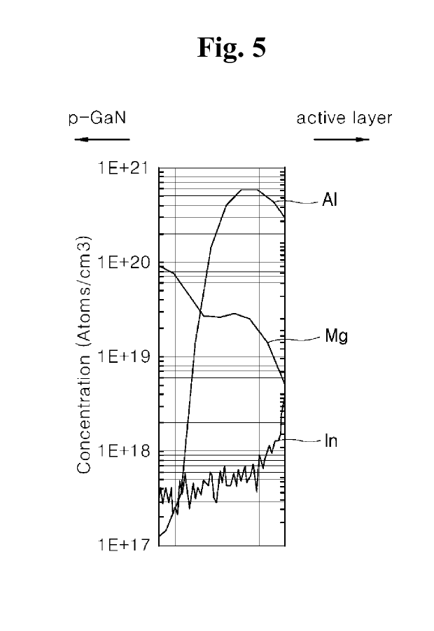

FIG. 5 shows the concentration profile of each of components contained in an electron blocking layer used in Comparative Example 1. As shown in FIG. 5, the electron blocking layer used in Comparative Example 1 was formed of AlGaN.

Table 1 below shows the results of evaluating the light emission and ESD characteristics of nitride semiconductor light-emitting devices including an electrode blocking layer used in Example 1 and an electrode blocking layer used in Comparative Example 1, respectively.

TABLE 1

| | Light emission characteristics | | ESD characteristics (survival rate) | | | | | |
|---|---|---|---|---|---|---|---|---|
| | VF@120 mA | PO@120 mA | 0.25 kV | 0.5 kV | 1 kV | 2 kV | 4 kV | 8 kV |
| Comparative | 3.15 | 100.00 | 100% | 100% | 100% | 90% | 70% | 0% |
| Example 1 | | | | | | | | |
| Example 1 | 3.14 | 102.73 | 100% | 100% | 100% | 100% | 100% | 100% |

As can be seen in Table 1 above, the nitride semiconductor light-emitting device including the electron blocking layer used in Example 1, and the nitride semiconductor light-emitting device including the electron blocking layer used in Comparative Example 1, had similar operating voltages, but the brightness of the nitride semiconductor light-emitting device of Example 1 was about 3% higher than the brightness of Comparative Example 1 (100%).

In addition, as can be seen in Table 1 above, the survival rate of Example 1 at a high voltage (4 kV or higher) was higher than that of Comparative Example 1, suggesting that the nitride semiconductor light-emitting device including the electron blocking layer used in Example 1 has excellent ESD characteristics.

Although the embodiments of the present invention have been described with reference to the accompanying drawings, the present invention is not limited to these embodiments, but may be modified in different forms. Those skilled in the art to which the present invention pertains will understand that the present invention may be embodied in other specific forms without departing from the technical spirit or essential characteristics of the present invention. Therefore, the embodiments described above are considered to be illustrative in all respects and not restrictive.

1. A nitride semiconductor light-emitting device comprising:
a first conductivity-type nitride semiconductor layer;
an active layer formed on the first conductivity-type nitride semiconductor layer;
a second conductivity-type nitride semiconductor layer formed on the active layer; and
an electron blocking layer formed between one of the first conductivity-type nitride semiconductor layer and the second conductivity-type nitride semiconductor layer, which is formed of a p-type nitride semiconductor, and the active layer, in which the electron blocking layer contains indium (In), and a concentration of indium (In) in the electron blocking layer increases as the electron blocking layer moves away from the active layer.

2. The nitride semiconductor light-emitting device of claim 1, wherein the electron blocking layer includes AlInGaN doped with a p-type impurity.

3. The nitride semiconductor light-emitting device of claim 2, wherein the active layer emits light having a blue wavelength, and a concentration of aluminum (Al) in the electron blocking layer is 15-20% of a total atomic number of aluminum (Al), indium (In) and gallium (Ga).

4. The nitride semiconductor light-emitting device of claim 2, wherein the active layer emits light having light having a UV wavelength, and a concentration of aluminum (Al) in the electron blocking layer is 20% or higher of a total atomic number of aluminum (Al), indium (In) and gallium (Ga).

5. The nitride semiconductor light-emitting device of claim 2, wherein the active layer emits light having light having a green wavelength, and a concentration of aluminum (Al) in the electron blocking layer is 15% or lower of a total atomic number of aluminum (Al), indium (In) and gallium (Ga).

6. The nitride semiconductor light-emitting device of claim 2, wherein a concentration of indium (In) in the electron blocking later is 0.2-1.5% of a total atomic number of aluminum (Al), indium (In) and gallium (Ga).

7. The nitride semiconductor light-emitting device of claim 2, wherein the concentration of the p-type impurity in the electron blocking layer increases as the electron blocking layer moves away from the active layer.

8. The nitride semiconductor light-emitting device of claim 2, wherein the concentration of indium in the electron blocking layer changes in proportion to the concentration of the p-type impurity in the electron blocking layer.

9. The nitride semiconductor light-emitting device of claim 8, wherein the concentration of the p-type impurity in the electron blocking layer is 1×10¹⁸ to 5×10²⁰ atoms/cm³.

10. The nitride semiconductor light-emitting device of claim 1, wherein the electron blocking layer has a thickness of 5-100 nm.

11. A nitride semiconductor light-emitting device comprising:
a first conductivity-type nitride semiconductor layer;
an active layer formed on the first conductivity-type nitride semiconductor layer;
a second conductivity-type nitride semiconductor layer formed on the active layer; and
an electron blocking layer formed between one of the first conductivity-type nitride semiconductor layer and the second conductivity-type nitride semiconductor layer, which is formed of a p-type nitride semiconductor, and the active layer, in which the electron blocking layer comprises a hole diffusion layer, a hole transport layer and a hole injection layer in a direction moving away from the active layer, and each of the hole diffusion layer, the hole transport layer and the hole injection layer contains indium (In) such that an average indium concentration of the hole injection layer is higher than the average indium concentration of the hole injection layer and the average indium concentration of the hole transport layer.

12. The nitride semiconductor light-emitting device of claim 11, wherein the average indium concentration of the hole transport layer is higher than the average indium concentration of the hole diffusion layer.

13. The nitride semiconductor light-emitting device of claim 11, wherein the concentration of indium shows a tendency to increase from the hole diffusion layer to the hole transport layer and from the hole transport layer to the hole injection layer.

14. The nitride semiconductor light-emitting device of claim 11, wherein each of the hole diffusion layer, the hole transport layer and the hole injection layer includes AlInGaN doped with a p-type impurity.

15. The nitride semiconductor light-emitting device of claim 14, wherein an average doping concentration of the p-type impurity in the hole injection layer is higher than the average doping concentration of the p-type impurity in the hole diffusion layer and the average doping concentration of the p-type impurity in the hole transport layer.

16. The nitride semiconductor light-emitting device of claim 15, wherein the average doping concentration of the p-type impurity in the hole transport layer is higher than the average doping concentration of the p-type impurity in the hole diffusion layer.

17. The nitride semiconductor light-emitting device of claim 15, wherein the concentration of the p-type impurity shows a tendency to increase from the hole diffusion layer to the hole transport layer and from the hole transport layer to the hole injection layer.
